(19) United States
(12) Patent Application Publication
(10) Pub. No.: US 2016/0139400 A1
(43) Pub. Date: May 19, 2016

(54) DISPLAY APPARATUS

(71) Applicant: Samsung Display Co., Ltd., Yongin-City (KR)

(72) Inventors: Jungwook LEE, Yongin-City (KR); Unbyoll KO, Yongin-City (KR); Jangil KIM, Yongin-City (KR); Seiyong PARK, Yongin-City (KR); Sunghee HONG, Yongin-City (KR)

(21) Appl. No.: 14/668,109

(22) Filed: Mar. 25, 2015

(30) Foreign Application Priority Data
Nov. 19, 2014 (KR) 10-2014-0161625

(51) Int. Cl. G02B 26/00; H01L 51/52; H01L 27/32; G02F 1/1335

(52) U.S. Cl. CPC G02B 26/004; G02F 1/133512; H01L 51/5281; H01L 27/3267; H01L 27/3286

(57) ABSTRACT

A display apparatus includes a display panel including a display device; and a light transmission control panel disposed to face one side of the display panel and configured to control a transmission amount of visible rays incident from the outside or visible rays generated from the display panel. The light transmission control panel includes a base member; a first electrode disposed on the base member; a second electrode disposed to face the first electrode; a polar fluid disposed between the first electrode and the second electrode, having a hydrophobic or hydrophilic surface characteristic, and having an electric polarity; and a blocking member disposed between the polar fluid and the first electrode, having an opposite surface characteristic to a surface characteristic of the polar fluid, and including a fluid configured to block at least some of the visible rays.

### RELATED APPLICATION

This application claims the benefit of Korean Patent Application No. 10-2014-0161625, filed on Nov. 19, 2014, in the Korean Intellectual Property Office, the disclosure of which is incorporated herein in its entirety by reference.

### BACKGROUND

1. Field

One or more exemplary embodiments relate to a display apparatus.

2. Description of the Related Art

Recently, uses of display apparatuses have become more diversified. In detail, a range of use of display apparatuses is expanding as display apparatuses become thinner and more light-weight.

Meanwhile, display apparatuses having variously changed characteristics are recently being developed.

For example, display apparatuses having various purposes may be implemented by enabling external light to transmit therethrough. For another example, reflection of external light may be used as a supply source for implementing an image of a display apparatus.

However, it is not easy to control display apparatuses using transmission of external light, and thus improvements in a characteristic of an image quality of display apparatuses are limited.

### SUMMARY

One or more exemplary embodiments include a display apparatus that improves a characteristic of an image quality and convenience of a user.

Additional aspects will be set forth in part in the description which follows and, in part, will be apparent from the description, or may be learned by practice of the presented embodiments.

According to one or more exemplary embodiments, a display apparatus includes: a display panel including a display device; and a light transmission control panel disposed to face one side of the display panel and configured to control a transmission amount of visible rays incident from the outside or visible rays generated from the display panel, wherein the light transmission control panel includes: a base member; a first electrode disposed on the base member; a second electrode disposed to face the first electrode; a polar fluid disposed between the first electrode and the second electrode, having a hydrophobic or hydrophilic surface characteristic, and having an electric polarity; and a blocking member disposed between the polar fluid and the first electrode, having an opposite surface characteristic to a surface characteristic of the polar fluid, and including a fluid configured to block at least some of the visible rays.

The display apparatus may further include an insulating layer disposed between the first electrode and the blocking member.

The insulating layer may have a hydrophobic or hydrophilic surface characteristic that is opposite to the surface characteristic of the polar fluid.

The fluid included in the blocking member may contain non-polar fluid.

The fluid included in the blocking member may contain colored oil.

The blocking member may further include a plurality of reflection particles configured to reflect the visible rays.

The plurality of reflection particles may include metal particles or white particles.

The base member, the first electrode, the second electrode, or the polar fluid may be formed such that the at least some of the visible rays is/are configured to be transmitted therethrough.

The light transmission control panel may further include a barrier wall disposed between the first electrode and the second electrode and configured to define a movement of the blocking member.

The barrier wall may have a hydrophobic or hydrophilic surface characteristic that is the same as the surface characteristic of the polar fluid.

The barrier wall may be disposed to correspond to a pixel or a sub pixel of the display panel.

An amount of external light incident through the light transmission control panel may be configured to be controlled by changing a degree of dispersion of the blocking member according to a movement of the polar fluid by controlling voltages applied to the first electrode and the second electrode.

The polar fluid may have an electrical conductivity.

The display panel may have a transmissive display structure in which at least some external light is configured to be transmitted in a direction opposite to a direction in which an image is formed.

The display panel may have a double-sided display structure in which an image is configured to be recognized on at least one surface and another surface.

The display panel may include: a liquid crystal panel including a liquid crystal display (LCD) device, a light guiding member disposed to face the liquid crystal panel and a light source unit configured to supply light to the light guiding member, wherein the light guiding member is disposed between the liquid crystal panel and the light transmission control panel.

The light source unit may be disposed to face side surfaces of the light guiding member.

The display apparatus may further include an optical cover disposed to correspond to a surface of the light source unit excluding a surface toward the light guiding member and blocking at least some of the light generated from the light source unit.

The optical cover may be disposed to surround the surface of the light source unit excluding the surface toward the light guiding member.

The display panel may include an organic light emitting device, wherein the organic light emitting device includes: a first device electrode, a second device electrode, and an intermediate layer disposed between the first device electrode and the second device electrode and including an organic emission layer configured to emit visible rays.

### BRIEF DESCRIPTION OF THE DRAWINGS

These and/or other aspects will become apparent and more readily appreciated from the following description of the exemplary embodiments, taken in conjunction with the accompanying drawings in which:

FIG. 1 is a schematic cross-sectional of a display apparatus according to an exemplary embodiment;

FIGS. 2A and 2B are enlarged views of a region A of FIG. 1;

FIG. 3 is a schematic cross-sectional of a display apparatus according to another exemplary embodiment;

FIG. 4 is an enlarged view of a region A of FIG. 3;

FIG. 5 is a schematic cross-sectional of a display apparatus according to another exemplary embodiment;

FIG. 6 is a schematic cross-sectional of a display panel included in the display apparatus of FIG. 5;

FIG. 7 is a schematic cross-sectional of a display apparatus according to another exemplary embodiment;

FIG. 8 is a schematic cross-sectional of a display panel included in the display apparatus of FIG. 7;

FIG. 9 is a schematic cross-sectional of a display apparatus according to another exemplary embodiment;

FIG. 10 is a schematic cross-sectional of a display panel included in the display apparatus of FIG. 9; and

FIG. 11 is an enlarged view of a region K of FIG. 10.

### DETAILED DESCRIPTION

Reference will now be made in detail to exemplary embodiments, examples of which are illustrated in the accompanying drawings. In this regard, the present exemplary embodiments may have different forms and should not be construed as being limited to the descriptions set forth herein. Accordingly, the exemplary embodiments are merely described below, by referring to the figures, to explain aspects of the present description.

It will be understood that although the terms “first”, “second”, etc. may be used herein to describe various components, these components should not be limited by these terms. These components are only used to distinguish one component from another.

As used herein, the singular forms “a,” “an” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “formed on,” another layer, region, or component, it can be directly or indirectly formed on the other layer, region, or component. That is, for example, intervening layers, regions, or components may be present.

Sizes of elements in the drawings may be exaggerated for convenience of explanation. In other words, since sizes and thicknesses of components in the drawings are arbitrarily illustrated for convenience of explanation, the following embodiments are not limited thereto.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

Hereinafter, one or more exemplary embodiments will be described below in more detail with reference to the accompanying drawings. Those components that are the same or are in correspondence are rendered the same reference numeral regardless of the figure number, and redundant explanations are omitted.

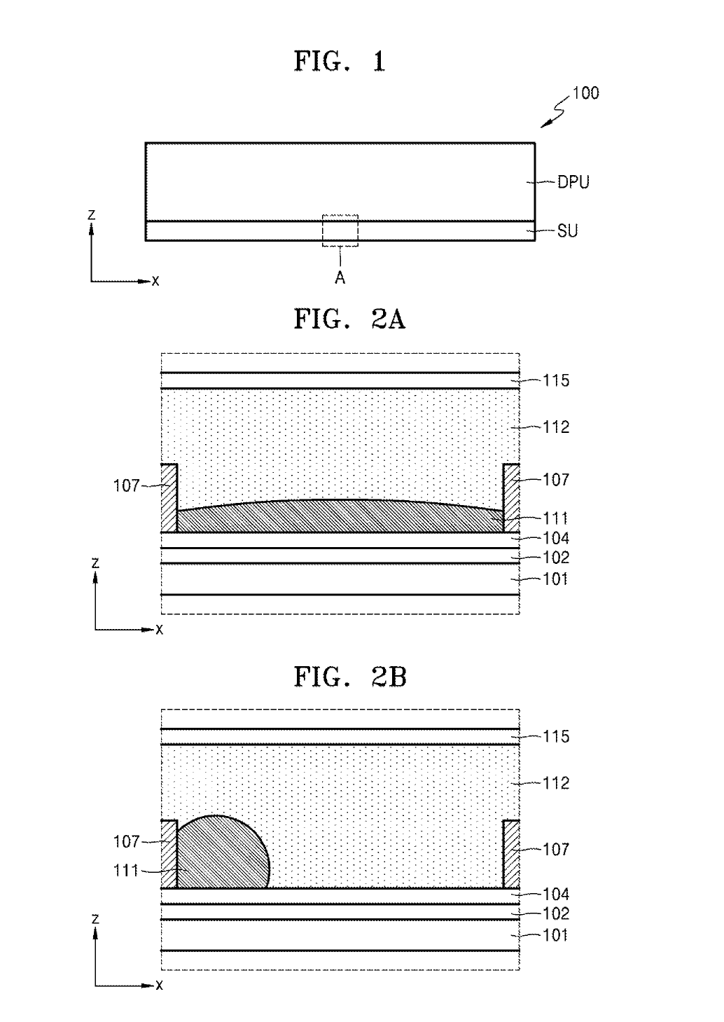

FIG. 1 is a schematic cross-sectional of a display apparatus 100 according to an exemplary embodiment. FIGS. 2A and 2B are enlarged views of a region A of FIG. 1.

Referring to FIG. 1, the display apparatus 100 includes a display panel DPU and a light transmission control panel SU.

The display panel DPU forms an image to a user but may include one or more devices. For example, the display panel DPU may include a display device such as an organic light emitting device or a liquid crystal display (LCD) device. The display panel DPU may further include various display devices.

According to a selective embodiment, the display panel DPU may have a transmissive display structure.

The light transmission control panel SU controls transmittance of visible rays. For example, the light transmission control panel SU may be formed such that at least some external light incident from a lower portion of the light transmission control panel SU may transmit at a desired time with respect to FIG. 1.

In the display panel DPU having a transmissive display structure as the selective embodiment described above, the display apparatus 100 has a transmissive display structure when the at least some external light incident from the lower portion of the light transmission control panel SU may transmit. That is, when a user is on an upper portion of FIG. 1, the user may recognize an image formed on the display panel DPU, and may also recognize an object present in a lower portion of the display apparatus 100 of FIG. 1.

According to a selective embodiment, the display panel DPU may have a double-sided display structure.

The light transmission control panel SU will now be described in more detail with reference to FIGS. 2A and 28.

The light transmission control panel SU includes a base member 101, a first electrode 102, a second electrode 115, a polar fluid 112, and a blocking member 111.

The base member 101 is formed of a material capable of transmitting the visible rays. For example, the base member 101 may be formed of a glass material having good light transmittance. The base member 101 may also be formed of a plastic material having the good light transmittance.

The first electrode 102 is disposed on the base member 101. The first electrode 102 may be formed of a material capable of transmitting at least a part of the visible rays. For example, the first electrode 102 may be formed of a transmittance conductive material.

The second electrode 115 is disposed to face the first electrode 102. According to a selective embodiment, the second electrode 115 may be formed of the material capable of transmitting the at least some of the visible rays.

The polar fluid 112 is disposed between the first electrode 102 and the second electrode 115. The polar fluid 112 may be formed of the material capable of transmitting the at least some of the visible rays. The polar fluid 112 may have a hydrophobic or hydrophilic surface characteristic, for example, the hydrophilic surface characteristic. As a specific example, the polar fluid 112 may contain water.

The blocking member 111 is disposed between the first electrode 102 and the second electrode 115. In more detail, the blocking member 111 may be disposed between the polar fluid 112 and the first electrode 102. According to a selective embodiment, an insulating layer 104 is disposed on the first electrode 102 and has the hydrophobic or hydrophilic surface characteristic. According to a selective embodiment, the insulating layer 104 may have the hydrophobic surface characteristic. If the polar fluid 112 has the hydrophobic surface characteristic, when no voltage is applied to the first electrode 102, as shown in FIG. 2A, the blocking member 111 may be broadly disposed on the insulating layer 104, and the polar fluid 112 is present on the blocking member 111. That is, the polar fluid 112 may be disposed far away from the insulating layer 104.

The blocking member 111 contains non-polar fluid. The blocking member 111 may have a different surface characteristic from a surface characteristic of the polar fluid 112. For example, when the polar fluid 112 has the hydrophilic surface characteristic, the blocking member 111 may contain fluid having the hydrophobic surface characteristic. The blocking member 111 may contain fluid of the material capable of transmitting the at least some of the visible rays. For example, the blocking member 11 may contain colored oil. The colored oil used to form the blocking member 111 may be formed by using various dyes or pigments.

The blocking member 111 is formed not to mix with the polar fluid 112.

According to a selective embodiment, a barrier wall 107 may be formed between the first electrode 102 and the second electrode 115. The barrier wall 107 may be formed to partition a predetermined space between the first electrode 102 and the second electrode 115. That is, the barrier wall 107 may partition the space defining a movement of the blocking member 111.

The barrier wall 107 may be formed of an insulating material, and, according to a selective embodiment, has the hydrophobic or hydrophilic surface characteristic. As a specific example, the barrier wall 107 may have a different surface characteristic from that of the blocking member 111 and the same surface characteristic as that of the polar fluid 112. For example, the barrier wall 107 may have the hydrophilic surface characteristic.

According to a selective embodiment, the barrier wall 107 may be formed to correspond to a pixel (not shown) or a sub pixel (not shown) of the display panel DPU.

Operations of the polar fluid 112 and the blocking member 111 before and after operating a power source (not shown) through the first electrode 102 and the second electrode 115 will be described with reference to FIGS. 2A and 2B.

For convenience of description, a case where the polar fluid 112 contains a material having the hydrophilic surface characteristic, for example, water, the blocking member 111 contains a material having the hydrophobic surface characteristic, for example, oil, the barrier wall 107 has the hydrophilic surface characteristic, and the insulating layer 104 has the hydrophobic surface characteristic will be described by way of example.

When no voltage is applied to the first electrode 102 and the second electrode 115 through the power source, as shown in FIG. 2A, the blocking member 111 has the hydrophobic surface characteristic and broadly spreads on the hydrophobic insulating layer 104. In this regard, a movement of the blocking member 111 is defined by the barrier wall 107.

The polar fluid 112 has the hydrophilic surface characteristic and is disposed on the blocking member 111 such that the polar fluid 112 may be spaced apart from the insulating layer 104.

When no voltage is applied to the first electrode 102 and the second electrode 115 through the power source, as shown in FIG. 2A, the blocking member 111 broadly and uniformly spreads on an upper surface of the insulating layer 104. The blocking member 111 is formed to block at least some of the visible rays. That is, the blocking member 111 is formed of the material such as the colored oil and prevents the visible rays from transmitting.

This restricts a transmission of the visible rays through the light transmission control panel SU. That is, with reference to FIG. 1, travel of external light incident to the display panel DPU through the light transmission control panel SU is blocked or reduced.

According to a selective embodiment, the display panel DPU may have a transmissive display structure. When the light transmission control panel DPU has such a structural characteristic of FIG. 2A, although a user who uses the display apparatus 100 may recognize an image formed on the display panel DPU irrespective of the light transmission control panel SU, the user may not recognize an object disposed on a lower portion of the light transmission control panel SU or a degree of recognition may be reduced. That is, although the display panel DPU has a transmissive display function, the display apparatus 100 may be used by omitting the transmissive display function.

According to a selective embodiment, when the display panel DPU has a double-sided display structure, when the light transmission control panel SU has a status of the structure of FIG. 2A, although the display panel DPU has the double-sided display structure, the display apparatus 100 may be used by omitting a double-side display function.

When voltages are applied to the first electrode 102 and the second electrode 115 through the power source, as shown in FIG. 2B, since the polar fluid 112 has a polarity, the polar fluid 112 moves toward the first electrode 102 such that the polar fluid 112 may be disposed adjacent to the first electrode 102, and the blocking member 111 is pushed by the polar fluid 112 and is present in a ball-like shape near the barrier wall 107 since the blocking member 111 is prevented from being pushed any farther by the barrier wall 107. In this regard, according to a selective embodiment, when the polar fluid 112 has an electrical conductivity, a movement of the polar fluid 112 may be faster.

The blocking member 111 has the hydrophobic surface characteristic and broadly spreads, e.g., moves, on the hydrophobic insulating layer 104, e.g., as it is displaced by the polar fluid 112. In this regard, a movement of the blocking member 111 is restricted by the barrier wall 107.

As described above, if voltages are applied to the first electrode 102 and the second electrode 115 through the power source, as shown in FIG. 2B, since the blocking member 111 is pushed by the polar fluid 112, the blocking member 111 is not present in a part corresponding to a most area of the upper surface of the insulating layer 104 and is present only in a small area adjacent to the barrier wall 107.

The visible rays may be transmitted through a region of the light transmission control panel SU corresponding to the insulating layer 104 in which the blocking member 111 is not present. That is, the external light incident through the light transmission control panel SU may travel toward the display panel DPU.

According to a selective embodiment, the display panel DPU may have the transmissive display structure. When the light transmission control panel SU has a status of the structure of FIG. 2B, the user who uses the display apparatus 100 may recognize the image formed on the display panel and recognize the object disposed on the lower portion of the light transmission control panel SU. That is, when the display panel DPU has the transmissive display function, the display apparatus 100 may be used as the transmissive display apparatus.

According to a selective embodiment, when the display panel DPU has the double-sided display structure, when the light transmission control panel SU has the status of the structure of FIG. 2B, the display apparatus 100 may be used by using a double-side function. That is, the user may recognize the image both in a direction in which a surface of the display apparatus 100 goes toward the display panel DPU and a direction in which the surface of the display apparatus 100 goes toward the light transmission control panel SU.

According to a selective embodiment, when the display panel DPU includes a type separately requiring a light source, for example, a LCD panel, the externally light incident through the light transmission control panel SU may be used as the light source, thereby improving light efficiency of the display panel DPU and an image quality characteristic.

The display apparatus 100 of the present embodiment includes the display panel DPU and the light transmission control panel SU. The light transmission control panel SU may include the blocking member 111 that may block at least some light. The light transmission control panel SU may control a degree of dispersion of the blocking member 111 by applying a voltage, thereby easily controlling transmittance of the visible rays incident to the display panel DPU.

In particular, when the display panel DPU has the transmissive display structure or the double-sided display structure according to a selective embodiment, the display panel DPU may control the light transmission control panel SU to use the transmissive display structure or the double-sided display structure at a desired time only, thereby improving convenience of the user.

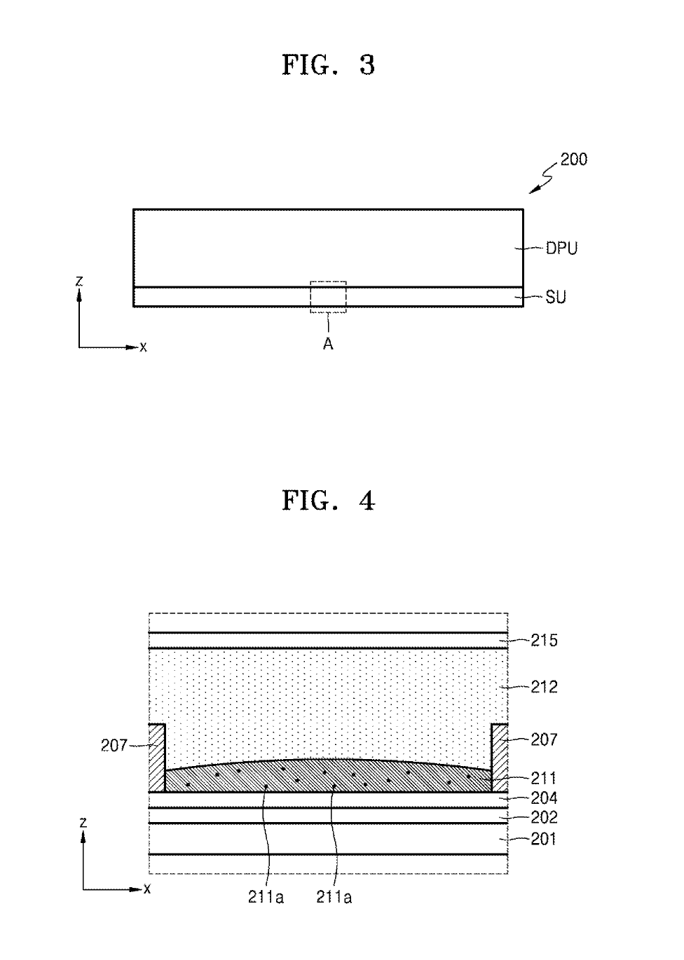

FIG. 3 is a schematic cross-sectional of a display apparatus 200 according to another exemplary embodiment. FIG. 4 is an enlarged view of a region A of FIG. 3.

Referring to FIG. 3, the display apparatus 200 includes the display panel DPU and the light transmission control panel SU.

A description of the display panel DPU is the same as described in the previous embodiment above, and thus a detailed description thereof is omitted.

The light transmission control panel SU controls transmission of visible rays. For example, the light transmission control panel SU may be formed such that at least some external light incident from a lower portion of the light transmission control panel SU may transmit at a desired time.

In the display panel DPU having a transmissive display structure according to a selective embodiment, the display apparatus 200 has transmissive display structure when the at least some external light incident from the lower portion of the light transmission control panel SU may transmit. That is, when a user is on an upper portion of FIG. 3, the user may recognize an image formed on the display panel DPU, and may also recognize an object present in a lower portion of the display apparatus 200 of FIG. 3.

According to a selective embodiment, the display panel DPU may have a double-sided display structure.

The light transmission control panel SU includes a base member 201, a first electrode 202, a second electrode 215, a polar fluid 212, and a blocking member 211.

Descriptions of the base member 201, the first electrode 202, the second electrode 215, and the polar fluid 212 are the same as described in the previous embodiment above, and thus detailed descriptions thereof are omitted.

The blocking member 211 is disposed between the first electrode 202 and the second electrode 215. In more detail, the blocking member 211 may be disposed between the polar fluid 212 and the first electrode 202. According to a selective embodiment, an insulating layer 204 is disposed on the first electrode 202 and has the hydrophobic or hydrophilic surface characteristic. According to a selective embodiment, the insulating layer 204 may have the hydrophobic surface characteristic. If the polar fluid 212 has the hydrophobic surface characteristic, when no voltage is applied to the first electrode 202, the blocking member 11 may broadly spread on the insulating layer 204, and the polar fluid 212 is present on the blocking member 211. That is, the polar fluid 212 may be disposed far away from the insulating layer 204.

The blocking member 211 contains non-polar fluid. The blocking member 211 may have a different surface characteristic from a surface characteristic of the polar fluid 212. For example, when the polar fluid 212 has the hydrophilic surface characteristic, the blocking member 211 may contain fluid having the hydrophobic surface characteristic. The blocking member 211 may contain fluid of the material capable of transmitting the at least some of the visible rays. For example, the blocking member 211 may contain colored oil. The colored oil used to form the blocking member 211 may be formed by using various dyes or pigments.

The blocking member 211 is formed not to mix with the polar fluid 212.

The blocking member 211 may contain a plurality of reflection particles 211a in addition to the non-polar fluid. The reflection particles 211a are formed to reflect at least some of the visible rays. According to a selective embodiment, the reflection particles 211a may be formed of a material having a good reflectivity. For example, the reflection particles 211a may contain metal particles, for specific examples, silver (Ag), aluminum (Al), zirconium (Zr), Zinc (Zn), copper, gold, platinum, nickel, etc.

For another example, the reflection particles 211a may contain white particles, for specific examples, a white ceramic material or a white organic material.

According to a selective embodiment, a barrier wall 207 may be formed between the first electrode 202 and the second electrode 215. The barrier wall 207 is the same as described in the previous embodiment above, and thus a detailed description thereof is omitted.

For example, when no voltage is applied to the first electrode 202 and the second electrode 215 through a power source, the blocking member 211 broadly spreads on an upper surface of the insulating layer 204. The blocking member 211 is formed to block at least some of the visible rays. That is, the blocking member 211 is formed of a material such as colored oil and prevents the visible rays from being transmitted.

This restricts transmission of the visible rays through the light transmission control panel SU. That is, with reference to FIG. 3, travel of external light incident to the display panel DPU through the light transmission control panel SU is blocked or reduced.

In particular, the blocking member 211 of the light transmissions control panel SU may contain the plurality of reflection particles 211a in addition to the non-polar fluid. A characteristic of an image quality of the display panel DPU may be improved owing to the reflection particles 211a. That is, the visible rays implemented on the display panel DPU may be reflected through the reflection particles 211a to travel toward the user. When the display panel DPU is a LCD panel, a backlight may be necessary as the light source. In this regard, the reflection particles 211a reflects light generated from the backlight to improve efficiency of het backlight, and thus the image quality characteristic of the display panel DPU may be improved.

Detailed descriptions of operations of the polar fluid 212 and the blocking member 211 before and after operating a power source (not shown) through the first electrode 202 and the second electrode 215 are the same as described with reference to FIGS. 2A and 2B, and thus the detailed descriptions thereof are omitted.

The display apparatus 200 of the present embodiment includes the display panel DPU and the light transmission control panel SU. The light transmission control panel SU may include the blocking member 211 that may block at least some light. The light transmission control panel SU may control a degree of dispersion of the blocking member 111 by applying a voltage, thereby easily controlling transmittance of the visible rays incident to the display panel DPU.

In particular, when the display panel DPU has the transmissive display structure or the double-sided display structure according to a selective embodiment, the display panel DPU may control the light transmission control panel SU to use the transmissive display structure or the double-sided display structure at a desired time only, thereby improving convenience of the user.

The blocking member 211 may include the plurality of reflection particles 211a, thereby easily improving a blocking effect of the external light. The image quality characteristic of the display panel DPU may be improved through the blocking member 211.

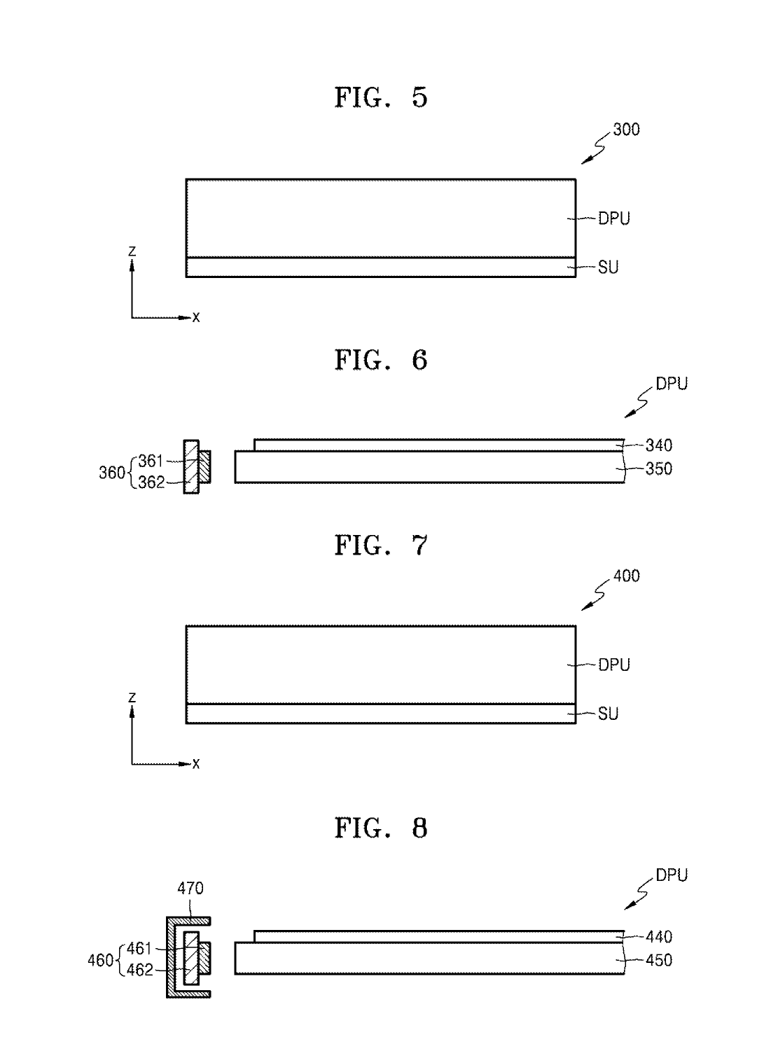

FIG. 5 is a schematic cross-sectional of a display apparatus 300 according to another exemplary embodiment. FIG. 6 is a schematic cross-sectional of the display panel DPU included in the display apparatus 300 of FIG. 5.

Referring to FIGS. 5 and 6, the display apparatus 300 includes the display panel DPU and the light transmission control panel SU. For convenience of description, differences between the present embodiment and the previous embodiments described above will be described below.

The light transmission control panel SU of the display apparatus 300 of the present embodiment may be one of the light transmission control panel SU of the display apparatus 100 and the light transmission control panel SU of the display apparatus 200 of the previous embodiments described above. The detailed description of the light transmission control panel SU is omitted.

The display panel DPU of the present embodiment includes a liquid crystal panel 340 including at least a LCD device, a light guiding member 350 disposed to face the liquid crystal panel 340, and a light source unit 360.

The liquid crystal panel 340 may include the LCD device to form an image toward a user. The LCD device may include a liquid crystal layer and one or more electrodes driving the liquid crystal layer. The liquid crystal panel 340 may further include a color conversion member disposed to correspond to the liquid crystal layer and implementing various colors, for example, a color filter.

The light guiding member 350 may be disposed to face the liquid crystal panel 340, more specifically, between the liquid crystal panel 340 and the light transmission control panel SU.

The light source unit 360 is disposed to correspond to side surfaces of the light guiding member 350 and includes a light source 361 and a support member 362 supporting the light source 361. The light source 361 is a member for generating light and may have various shapes. For example, the light source 361 may include a fluorescent lamp or a light emitting diode, etc. The light source 361 supplies light to the liquid crystal panel 340. In this regard, the light generated from the light source 361 may be incident to the light guiding member 350 and may be uniformly supplied to the liquid crystal panel 340 so as to uniformly spread the light and improve optical efficiency.

The support member 362 may support the light source 361 and may include a circuit member (not shown) for driving the light source 361 according to a selective embodiment.

According to a selective embodiment, the display panel DPU may have a transmissive display structure. That is, the liquid crystal panel 340 and the light guiding member 350 may be formed to transmit at least some of the visible rays.

According to a selective embodiment, the display panel DPU may have a double-sided display structure.

The display apparatus 300 of the present embodiment includes the display panel DPU and the light transmission control panel SU. The light transmission control panel SU may include a blocking member, e.g., as discussed above, that may block at least some light. The light transmission control panel SU may control a degree of dispersion of the blocking member by applying a voltage, thereby easily controlling transmittance of the visible rays incident to the display panel DPU.

In particular, when the display panel DPU has the transmissive display structure or the double-sided display structure according to a selective embodiment, the display panel DPU may control the light transmission control panel SU to use the transmissive display structure or the double-sided display structure at a desired time only, thereby improving convenience of the user.

The blocking member may include a plurality of reflection particles, thereby easily improving a blocking effect of the external light. An image quality characteristic of the display panel DPU may be improved through the blocking member.

In particular, the display panel DPU of the present embodiment includes the liquid crystal panel 340, the light guiding member 350 disposed to correspond to the liquid crystal panel 340, and the light source unit 360. The light guiding member 350 is disposed between the liquid crystal panel 340 and the light transmission control panel SU. External light is transferred through the light transmission control panel SU to the light guiding member 350, and then is transferred to the liquid crystal panel 340, thereby improving the image quality characteristic implemented through the liquid crystal panel 340 and reducing a power consumption of the display panel DPU. When the light transmission control panel SU is disposed to block at least some of the external light, in particular, the blocking member includes reflection particles, light incident from the light source unit 360 to the light guiding unit 350 may be reflected by the light transmission control panel SU, thereby improving efficiency of supply of the light to the liquid crystal panel 340, improving the image quality characteristic implemented through the liquid crystal panel 340 and reducing a power consumption of the display panel DPU.

FIG. 7 is a schematic cross-sectional of a display apparatus 400 according to another exemplary embodiment. FIG. 8 is a schematic cross-sectional of the display panel DPU included in the display apparatus 400 of FIG. 7.

Referring to FIGS. 7 and 8, the display apparatus 400 includes the display panel DPU, the light transmission control panel SU, and an optical cover 470. For convenience of description, differences between the present embodiment and the previous embodiments described above will be described below.

The light transmission control panel SU of the display apparatus 400 of the present embodiment may be one of the light transmission control panel SU of the display apparatus 100 and the light transmission control panel SU of the display apparatus 200 of the previous embodiments described above. The detailed description of the light transmission control panel SU is omitted.

The display panel DPU of the present embodiment includes a liquid crystal panel 440 including at least a LCD device, a light guiding member 450 disposed to face the liquid crystal panel 440, and a light source unit 460.

The liquid crystal panel 440 may include the LCD device to form an image toward a user. The LCD device may include a liquid crystal layer and one or more electrodes driving the liquid crystal layer. The liquid crystal panel 440 may further include a color conversion member disposed to correspond to the liquid crystal layer and implementing various colors, for example, a color filter.

The light guiding member 450 may be disposed to face the liquid crystal panel 440, more specifically, between the liquid crystal panel 440 and the light transmission control panel SU.

The light source unit 460 is disposed to correspond to side surfaces of the light guiding member 450 and includes a light source 461 and a support member 462 supporting the light source 461. The light source 461 is a member for generating light and may have various shapes. For example, the light source 461 may include a fluorescent lamp or a light emitting diode, etc. The light source 461 supplies light to the liquid crystal panel 440. In this regard, the light generated from the light source 461 may be incident to the light guiding member 450 and may be uniformly supplied to the liquid crystal panel 440 so as to uniformly spread the light and improve optical efficiency.

The support member 462 may support the light source 461 and may include a circuit member (not shown) for driving the light source 461 according to a selective embodiment.

The display apparatus 400 of the present embodiment includes the optical cover 470. The optical cover 470 may be disposed to correspond to the light source unit 460, in more detail, a surface of the light source unit 460 excluding a surface toward the light guiding member 450. According to a selective embodiment, the optical cover 470 may be formed to surround the surface of the light source unit 460 excluding the surface toward the light guiding member 450. Thus, light generated from the light source unit 460 may be effectively flown, e.g., directed, to the light guiding member 450. To this end, according to a selective embodiment, the optical cover 470 is formed to block at least some of the light generated from the light source unit 460. According to a selective embodiment, a surface of the optical cover 470 toward the light source unit 460 is formed as a reflection surface, thereby improving efficiency of flow of the light from the light source unit 460 to the light guiding member 450.

When a user directly recognizes the light generated from the light source unit 460, a recognition characteristic with respect to an image formed on the display panel DPU may deteriorate. In the present embodiment, the light generated from the light source unit 460 is reduced or blocked from being directly transferred to the user, e.g., without first being transferred through the light guiding member 450 and the liquid crystal panel 440, by the optical cover 470, thereby improving an image quality characteristic of the display panel DPU.

According to an embodiment, the display panel DPU may have a transmissive display structure. That is, the liquid crystal panel 440 and the light guiding member 450 may be formed to transmit at least some of the visible rays.

According to a selective embodiment, the display panel DPU may have a double-sided display structure.

The display apparatus 400 of the present embodiment includes the display panel DPU and the light transmission control panel SU. The light transmission control panel SU may include a blocking member that may block at least some light. The light transmission control panel SU may control a degree of dispersion of the blocking member by applying a voltage, thereby easily controlling transmittance of the visible rays incident to the display panel DPU.

In particular, when the display panel DPU has the transmissive display structure or the double-sided display structure according to a selective embodiment, the display panel DPU may control the light transmission control panel SU to use the transmissive display structure or the double-sided display structure at a desired time only, thereby improving convenience of the user.

The blocking member may include a plurality of reflection particles, thereby easily improving a blocking effect of the external light. An image quality characteristic of the display panel DPU may be improved through the blocking member.

In particular, the display panel DPU of the present embodiment includes the liquid crystal panel 440, the light guiding member 450 disposed to correspond to the liquid crystal panel 440, and the light source unit 460. The light guiding member 450 is disposed between the liquid crystal panel 440 and the light transmission control panel SU. External light is transferred through the light transmission control panel SU to the light guiding member 450, and then is transferred to the liquid crystal panel 440, thereby improving the image quality characteristic implemented through the liquid crystal panel 440 and reducing a power consumption of the display panel DPU. When the light transmission control panel SU is disposed to block at least some of the external light, in particular, the blocking member includes reflection particles, light incident from the light source unit 460 to the light guiding unit 450 may be reflected by the light transmission control panel SU, thereby improving efficiency of supply of the light to the liquid crystal panel 440, improving the image quality characteristic implemented through the liquid crystal panel 440 and reducing a power consumption of the display panel DPU.

Also, the image quality characteristic of the display panel DPU may be improved by the optical cover 470.

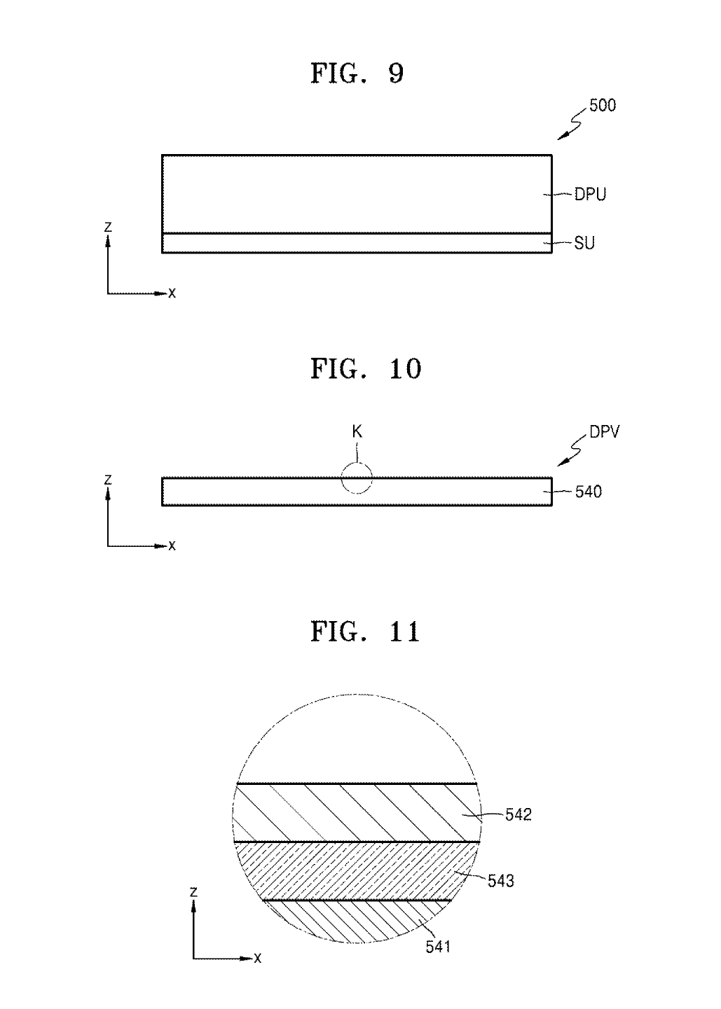

FIG. 9 is a schematic cross-sectional of a display apparatus 500 according to another exemplary embodiment. FIG. 10 is a schematic cross-sectional of the display panel DPU included in the display apparatus 500 of FIG. 9. FIG. 11 is an enlarged view of a region K of FIG. 10.

Referring to FIGS. 9 through 11, the display apparatus 500 includes the display panel DPU and the light transmission control panel SU. For convenience of description, differences between the present embodiment and the previous embodiments described above will be described below.

The light transmission control panel SU of the display apparatus 500 of the present embodiment may be one of the light transmission control panel SU of the display apparatus 100 and the light transmission control panel SU of the display apparatus 200 of the previous embodiments described above. The detailed description of the light transmission control panel SU is omitted.

The display panel DPU of the present embodiment includes an organic light emitting device (OLED) 540.

The OLED 540 includes a first device electrode 541, a second device electrode 542, and an intermediate layer 543 disposed between the first device electrode 541 and the second device electrode 542. The intermediate layer 543 includes an organic emission layer to emit visible rays.

The first device electrode 541 functions as an anode, and the second device electrode 542 functions as a cathode. Polarities of the first device electrode 541 and the second device electrode 542 may be switched.

When the first device electrode 541 functions as the anode, the first device electrode 541 may be formed of indium tin oxide (ITO), indium zinc oxide (ED), zinc oxide (ZnO), or indium oxide (In2O3) that have a high work function. The first device electrode 541 may include a reflective film formed of silver (Ag), magnesium (Mg), aluminum (Al), platinum (Pt), palladium (Pd), gold (Au), nickel (Ni), neodymium (Nd), iridium (fr). chromium (Cr), lithium (Li), ytterbium (Yb), or calcium (Ca) according to an objective and a design condition.

When the second device electrode 542 functions as the cathode, the second device electrode 542 may be formed of a metal, such as Ag, Mg, Al, Pt, Pd, Au, Ni, Nd, Ir, Cr, Li, or Ca. As another embodiment, the second device electrode 542 may be formed of ITO, IZO, ZnO, or In203 to have a good light transmittance.

The intermediate layer 543 includes the organic emission layer to emit the visible rays. For example, the intermediate layer 543 may include the organic emission layer and may further include at least one of a hole injection layer (HIL), a hole transport layer (HTL), an electron transport layer (ETL), and an electron injection layer (EIL).

If voltages are applied to the first device electrode 541 and the second device electrode 542, the visible rays are generated in the organic emission layer of the intermediate layer 543.

Although not shown, the display panel DPU of the present embodiment may include one or more thin film transistors (not shown) electrically connected to the OLED 540. The display panel DPU may include one or more capacitors electrically connected to the OLED 540.

According to a selective embodiment, the display panel DPU may have a transmissive display structure. According to a selective embodiment, the display panel DPU may have a double-sided display structure.

The display apparatus 500 of the present embodiment includes the display panel DPU and the light transmission control panel SU. The light transmission control panel SU may include a blocking member that may block at least some light. The light transmission control panel SU may control a degree of dispersion of the blocking member 111 by applying a voltage, thereby easily controlling transmittance of the visible rays incident to the display panel DPU.

In particular, when the display panel DPU has the transmissive display structure or the double-sided display structure according to a selective embodiment, the display panel DPU may control the light transmission control panel SU to use the transmissive display structure or the double-sided display structure at a desired time only, thereby improving convenience of the user.

The blocking member may include a plurality of reflection particles, thereby easily improving a blocking effect of the external light. An image quality characteristic of the display panel DPU may be improved through the blocking member.

As described above, according to one or more exemplary embodiments, a display apparatus may easily improve a characteristic of an image quality and convenience of a user.

While one or more exemplary embodiments have been described with reference to the figures, it will be understood by those of ordinary skill in the art that various changes in form and details may be made therein without departing from the spirit and scope as defined by the following claims.

What is claimed is:

1. A display apparatus comprising:
a display panel comprising a display device; and
a light transmission control panel disposed to face one side of the display panel and configured to control a transmission amount of visible rays incident from the outside or visible rays generated from the display panel,
wherein the light transmission control panel comprises:
a base member;
a first electrode disposed on the base member;
a second electrode disposed to face the first electrode;
a polar fluid disposed between the first electrode and the second electrode, having a hydrophobic or hydrophilic surface characteristic, and having an electric polarity; and
a blocking member disposed between the polar fluid and the first electrode, having an opposite surface characteristic to a surface characteristic of the polar fluid, and comprising a fluid configured to block at least some of the visible rays.

2. The display apparatus of claim 1, further comprising an insulating layer disposed between the first electrode and the blocking member.

3. The display apparatus of claim 2, wherein the insulating layer has a hydrophobic or hydrophilic surface characteristic that is opposite to the surface characteristic of the polar fluid.

4. The display apparatus of claim 1, wherein the fluid included in the blocking member contains non-polar fluid.

5. The display apparatus of claim 1, wherein the fluid included in the blocking member contains colored oil.

6. The display apparatus of claim 1, wherein the blocking member further comprises a plurality of reflection particles configured to reflect the visible rays.

7. The display apparatus of claim 6, wherein the plurality of reflection particles comprise metal particles or white particles.

8. The display apparatus of claim 1, wherein the base member, the first electrode, the second electrode, or the polar fluid is formed such that the at least some of the visible rays is/are configured to be transmitted therethrough.

9. The display apparatus of claim 1, wherein the light transmission control panel further comprises a barrier wall disposed between the first electrode and the second electrode and configured to define a movement of the blocking member.

10. The display apparatus of claim 9, wherein the barrier wall has a hydrophobic or hydrophilic surface characteristic that is the same as the surface characteristic of the polar fluid.

11. The display apparatus of claim 9, wherein the barrier wall is disposed to correspond to a pixel or a sub pixel of the display panel.

12. The display apparatus of claim 1, wherein an amount of external light incident through the light transmission control panel is configured to be controlled by changing a degree of dispersion of the blocking member according to a movement of the polar fluid by controlling voltages applied to the first electrode and the second electrode.

13. The display apparatus of claim 1, wherein the polar fluid has an electrical conductivity.

14. The display apparatus of claim 1, wherein the display panel has a transmissive display structure in which at least some external light is configured to be transmitted in a direction opposite to a direction in which an image is formed.

15. The display apparatus of claim 1, wherein the display panel has a double-sided display structure in which an image is configured to be recognized on at least one surface and another surface.

16. The display apparatus of claim 1, wherein the display panel comprises: a liquid crystal panel comprising a liquid crystal display (LCD) device, a light guiding member disposed to face the liquid crystal panel and a light source unit configured to supply light to the light guiding member,
wherein the light guiding member is disposed between the liquid crystal panel and the light transmission control panel.

17. The display apparatus of claim 16, wherein the light source unit is disposed to face side surfaces of the light guiding member.

18. The display apparatus of claim 16, further comprising: an optical cover disposed to correspond to a surface of the light source unit excluding a surface toward the light guiding member and blocking at least some of the light generated from the light source unit.

19. The display apparatus of claim 18, wherein the optical cover is disposed to surround the surface of the light source unit excluding the surface toward the light guiding member.

20. The display apparatus of claim 1, wherein the display panel comprises an organic light emitting device,
wherein the organic light emitting device comprises: a first device electrode, a second device electrode, and an intermediate layer disposed between the first device electrode and the second device electrode and comprising an organic emission layer configured to emit visible rays.
